(19) United States
(12) Patent Application Publication
(10) Pub. No.: US 2021/0056426 A1
(43) Pub. Date: Feb. 25, 2021

(54) GENERATION OF KERNELS BASED ON PHYSICAL STATES

(71) Applicant: Hewlett-Packard Development Company, L.P., Spring, TX (US)

(72) Inventors: He Luan, Palo Alto, CA (US); Jun Zeng, Palo Alto, CA (US)

(73) Assignee: Hewlett-Packard Development Company, L.P., Spring, TX (US)

(21) Appl. No.: 16/966,529

(22) PCT Filed: Mar. 26, 2018
(86) PCT No.: PCT/US2018/024269

§ 371 Date: Jul. 31, 2020

(51) Int. Cl. G06N 3/08; G06F 9/54; G06T 7/90; G06F 30/20

(52) U.S. Cl. CPC G06N 3/084; G06F 30/20; G06T 7/90; G06F 9/545

(57) ABSTRACT

An example system includes a kernel generation engine. The kernel generation engine is to generate a plurality of kernels based on a description of a physical state. The plurality of kernels are generated based on applying a neural network to the description of the physical state. The system includes a calculation engine to apply the plurality of kernels to the description of the physical state to produce a plurality of intermediate descriptions. The system includes a weighting engine to determine a plurality of weight maps based on the plurality of kernels. The system includes a compositing engine to apply the plurality of weight maps to the plurality of intermediate descriptions to produce weighted intermediate descriptions and to combine the weighted intermediate descriptions to produce an updated description of the physical state.

### BACKGROUND

Various physical phenomena can be modeled using computers. For example, a computer may store data representative of a physical phenomenon. A complete dataset may be copied to the computer, or the computer may receive the data from a sensor, for example, over time. The computer may perform various operations on the data to further represent additional aspects of the physical phenomenon. Accordingly, the computer may provide a deeper understanding of the physical phenomena being modeled.

### BRIEF DESCRIPTION OF THE DRAWINGS

FIG. 1 is a block diagram of an example system to generate a kernel based on a physical state.

FIG. 2 is a block diagram of another example system to generate a kernel based on a physical state.

FIG. 3 is a flow diagram of an example method to update models to generate a kernel.

FIG. 4 is a flow diagram of an example method to compute an array of estimated temperature values.

FIG. 5 is a flow diagram of another example method to update models to generate a kernel.

FIG. 6 is a block diagram of an example computer-readable medium including instructions that cause a processor to generate a kernel based on a physical state.

FIG. 7 is a block diagram of another example computer-readable medium including instructions that cause a processor to generate a kernel based on a physical state.

### DETAILED DESCRIPTION

In some examples, physical phenomena may be complicated to model by a computer. For example, some physical phenomena may be anisotropic, such as thermal diffusivity in heterogeneous or anisotropic materials, conductivity in particular materials (e.g., electrical conductivity in certain crystals), stiffness of particular materials, or the like. The physical phenomena may depend on several physical attributes. For example, thermal diffusivity may depend on the temperature field and phase properties at a location and at neighboring locations. Aspects of the physical phenomena may be modeled at numerous locations, and numerous calculations may be performed for each location to account for the various interactions occurring at each location and among neighboring locations. However, such modeling may quickly lead to performing extraordinarily large numbers of calculations. Such large numbers of calculations may be time consuming to perform and may take too long to be usable in many situations.

In an example, a printer, such as a three-dimensional printer, may deliver thermal energy to a print target, such as a print bed where loose powder is fused or sintered layer-by-layer to build a printed part. The printer may also deliver chemical agents (e.g., property changing agents, such as fusing agents, detailing agents, etc.) selectively on the print target to eventually trigger phase changes and drive the powder at selected locations to be fused together. Accordingly, the volume elements (“voxels”) of the print target may include different materials relative to one another. The thermal diffusivity of each voxel may depend on the properties of that voxel as well as the properties of neighboring voxels. These properties may depend on the materials contained in each voxel or the current state of those materials, which materials and states may vary due to the heterogeneity of the voxels. Accordingly, thermal diffusion in the printer may be anisotropic and may be complicated to model. Significant numbers of calculations may be involved in modeling thermal diffusion over even short periods of time. Modeling of complicated physical phenomena, such as anisotropic phenomena (e.g., thermal diffusion in three-dimensional printers), may be improved by providing models that permit reasonable numbers of calculations to be performed while modeling the physical phenomena.

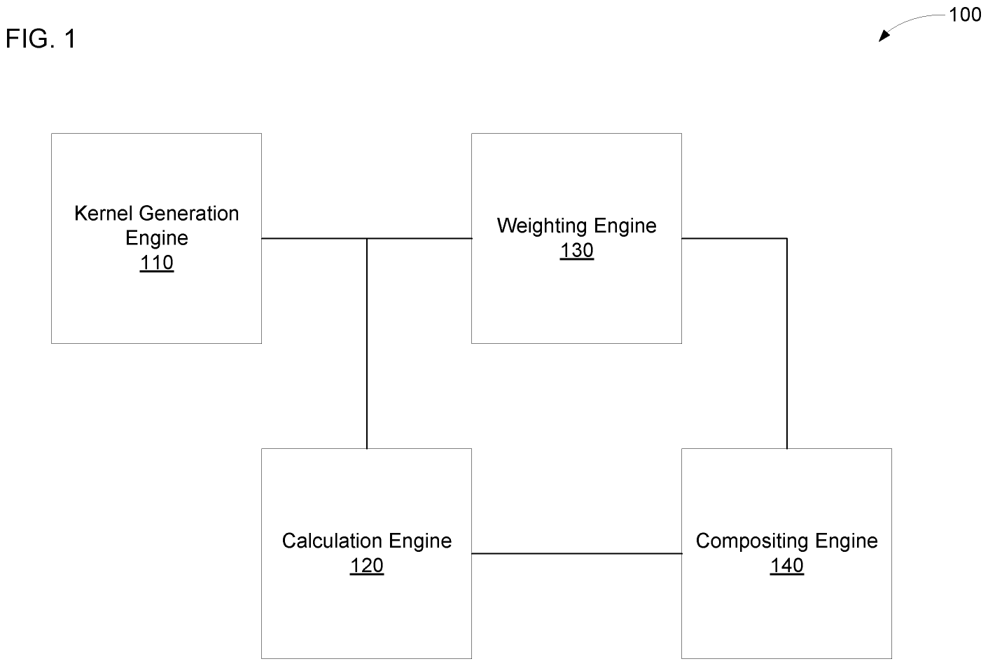

FIG. 1 is a block diagram of an example system 100 to generate a kernel based on a physical state. The system 100 may include a kernel generation engine 110. As used herein, the term “engine” refers to hardware (e.g., a processor, such as an integrated circuit or other circuitry) or a combination of software (e.g., programming such as machine- or processor-executable instructions, commands, or code such as firmware, a device driver, programming, object code, etc.) and hardware. Hardware includes a hardware element with no software elements such as an application specific integrated circuit (ASIC), a Field Programmable Gate Array (FPGA), etc. A combination of hardware and software includes software hosted at hardware (e.g., a software module that is stored at a processor-readable memory such as random access memory (RAM), a hard-disk or solid-state drive, resistive memory, or optical media such as a digital versatile disc (DVD), and/or executed or interpreted by a processor), or hardware and software hosted at hardware.

The kernel generation engine 110 may generate a plurality of kernels based on a description of a physical state. As used herein, the term “description of a physical state” refers to data indicative of characteristics of a physical system. For example, the data may include raw or processed measurements of the physical system. As used herein, the term “kernel” refers to an indication of a relationship between inputs to the kernel and outputs from the kernel. For example, the kernel may indicate the relationship between a description of a physical state of a physical system at a first time and a description of a physical state of the physical system at a second time. Such relationship may reflect a physical law. In an example, the plurality of kernels are generated based on applying a neural network (e.g., a deep neural network) to the description of the physical state. For example, the description of the physical state may be used as an input to the neural network, and the neural network may produce the plurality of kernels based on the input.

The system 100 may include a calculation engine 120 to apply the plurality of kernels to the description of the physical state to produce a plurality of intermediate descriptions. For example, the description of the physical state may be used as an input to each kernel. Each kernel may produce an intermediate description as an output. Accordingly, there may be a corresponding number of kernels and intermediate descriptions.

The system 100 may include a weighting engine 130 to determine a plurality of weight maps based on the plurality of kernels. For example, the weighting engine 130 may determine how much weight should be accorded to various portions of each intermediate description based on the kernel that produced the intermediate description. Each weight map may indicate the weight to be applied to each portion of the corresponding intermediate description.

The system 100 may include a compositing engine 140 to apply the plurality of weight maps to the plurality of intermediate descriptions to produce weighted intermediate descriptions. For example, each portion of each intermediate description may be weighted as indicated by the corresponding portion of the corresponding weight map. The compositing engine 140 may combine the weighted intermediate descriptions to produce an updated description of the physical state. In some examples, the compositing engine 140 may combine the weighted intermediate descriptions by computing a sum, an arithmetic or geometric mean, a median, a mode, a minimum, a maximum, or the like.

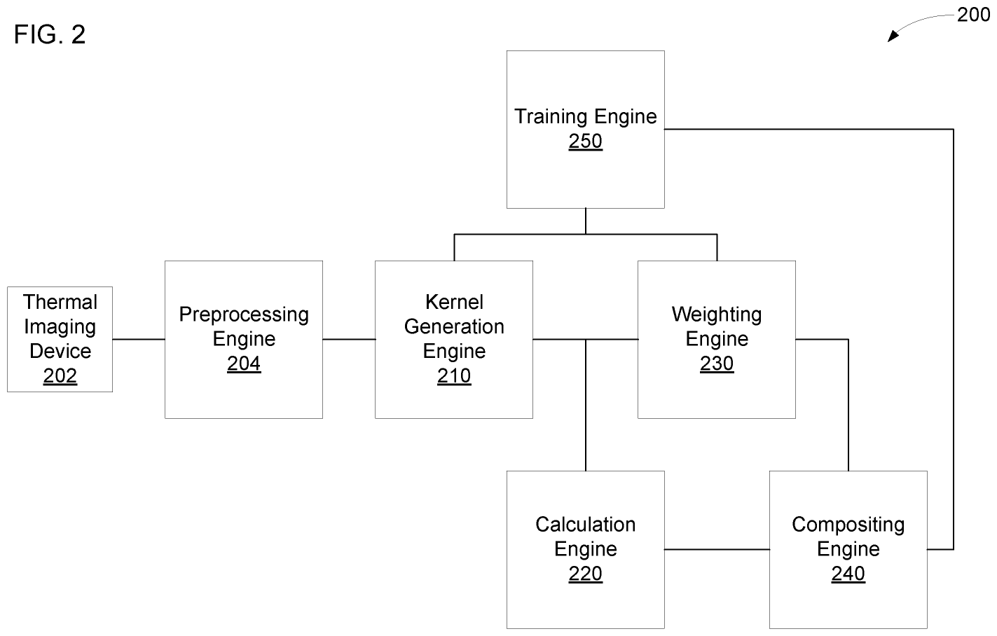

FIG. 2 is a block diagram of another example system 200 to generate a kernel based on a physical state. The system 200 may include a thermal imaging device 202. The thermal imaging device 202 may generate a thermal image by sensing infrared radiation at a plurality of picture elements (pixels) at a point in time. As used herein, the term “point in time” refers to a time period that is short relative to the time spans over which measurable changes occur to a physical state being measured. For example, the length of the point in time may correspond to the shutter speed of the thermal imaging device. Each pixel of the thermal image may correspond to the intensity of the infrared radiation at that pixel. In an example, the thermal imaging device 202 may capture a thermal image of a print target. The thermal imaging device 202 may capture an overhead view of the print target and thus depict an x-y plane.

In an example, the thermal imaging device 202 may capture a first thermal image of a first layer of powder on the print target and a second thermal image of a second layer of powder on the print target. For example, the thermal imaging device 202 may capture the first thermal image immediately prior to the second layer of powder being added on top of the first layer of powder. As used herein, the term “immediately prior” refers to capturing the thermal image when little change will occur to the physical state being measured before the next layer is added. In an example, the thermal image device 202 may be associated with a frame rate, and the last frame captured before adding the second layer of powder may be captured immediately prior to the addition of the second layer of powder. As used herein, the terms “first” and “second” are used to differentiate between different elements and may not indicate position. For example, the first layer of powder may not be a bottom layer of powder.

The system 200 may include a preprocessing engine 204. The preprocessing engine 204 may correct the thermal image to compensate for distortion caused by the thermal imaging device 202 (e.g., distortion caused by a lens or camera angle of the thermal imaging device 202). For example, straight lines on the print target may appear as curved lines in the thermal image. The preprocessing engine 204 may apply an inversion of the distortion to the thermal image, for example, so that straight lines on the print target appear as straight lines in the corrected thermal image. The preprocessing engine 204 may convert the thermal image into an array of temperature values at the point in time. As used herein, the term “array” refers to a group of data elements (e.g., data elements indicative of temperature values). The array may be a multidimensional array, such as a two-dimensional array with the dimensions corresponding to the dimensions of the corrected thermal image. In an example, the preprocessing engine 204 may compute the temperature values from the intensity values based on a predetermined or measured relationship between intensity and temperature.

The system 200 may include a kernel generation engine 210. In an example, the kernel generation engine 210 may generate a plurality of kernels based on the array of temperature values. In other examples, the kernel generation engine 210 may generate the plurality of kernels based on a description of a physical state other than the array of temperature values (e.g., a thermal image, an array of electric potentials or currents, an array of stresses or strains, etc.). The kernel generation engine 210 may use a model to compute the plurality of kernels based on the array of temperature values. In some examples, the model may include a neural network, such as a convolutional neural network. The array of temperature values may be input to the convolutional neural network. In some examples, the array of temperature values may be a difference between two arrays of temperature values (e.g., the difference between a first array corresponding to a first thermal image of a first layer of powder and a second array corresponding to a second thermal image of a second layer of powder).

In an example, the input to the convolutional neural network may include a two-dimensional array of temperature values. The layers in the convolutional neural network and the output of the convolutional neural network may include three-dimensional arrays of values. For example, the size of the third dimension of the output may be equal to the number of kernels to be generated. The hidden layers of the convolutional neural network may include third dimensions with sizes equal to the number of kernels to be generated, that are integer multiples of the number of kernels to be generated, or the like. For example, there may be three kernels and a 100×100 array of temperature values in an example. The input may be the 100×100 array of temperature values, a second layer may produce a 33×33×6 array of values, a third layer may produce an 11×11×6 array of values, and an output of the convolutional neural network may be a 5×5×3 array of values. In some examples, an alternate description of the physical state may also be included in the input. For example, the input may include an array of temperature values and an array of alternate values associated with the print target (e.g., the input may include a three dimensional array constructed from a plurality of two dimensional arrays variously describing a physical state of a physical system). The array of alternate values may include fusing or detailing agent distribution maps (e.g., maps that indicate the phase or material status of each voxel), distribution maps of other chemical agents, intensities from a visible light image of the print target, or the like. In an example, each kernel may include an array of values. For example, each kernel may include a two dimensional array of values, and the output of the convolutional neural network may include a three dimensional array that includes the plurality of kernels. In such an example, the kernel may not explicitly indicate the calculations relating inputs to the kernel to outputs to the kernel, but rather the kernel may include an array of values used in predetermined calculations.

The system 200 may include a calculation engine 220. The calculation engine 220 may apply the plurality of kernels to the description of the physical state to produce a plurality of intermediate descriptions. For example, the calculation engine 220 may receive the array of temperature values as an input and calculate each of a plurality of intermediate arrays of values based on the array of temperature values and one of the plurality of kernels. In an example, the calculation engine 220 may compute each intermediate array of values by convolving each kernel with the array of temperature values. Accordingly, each intermediate array may correspond to one of the plurality of kernels. In some examples, another function, such as a cross-correlation, may be used rather than a convolution. In some examples, the calculation engine 220 may apply the plurality of kernels to the difference between two arrays of temperature values. In an example, the kernel generation engine 210 may generate the plurality of kernels using one of the two arrays of temperature values as an input to the neural network, and the calculation engine 220 may apply the plurality of kernels to the difference. There may be three kernels and a 100×100 array of temperature values in an example. The result of the convolution operations may be a 100×100×3 array of intermediate values (e.g., three 100×100 arrays of values).

The plurality of kernels may model thermal diffusion between an element of the array of temperature values and nearby elements of the array of temperature values. Such nearby elements may represent areas neighboring a particular location on the print target and that may act as heat sources or heat sinks affecting the thermal diffusion to or from that particular location. Various physical attributes may affect the thermal diffusion, so each kernel may model a different physical attribute related to the thermal diffusion. Each kernel may model the pattern of thermal diffusion that will occur from nearby elements when accounting for a particular physical attribute. The convolutional neural network may be trained to generate kernels that model the physical attributes rather than the convolutional neural network itself modeling the physical attributes. In an example, each kernel may be a 5×5 array of values so that the kernels account for thermal diffusion from two neighboring elements in each direction.

The system 200 may include a weighting engine 230. The weighting engine 230 may determine a plurality of weight maps based on the plurality of kernels. Different physical attributes may be dominant for different temperature values or under different conditions. Accordingly, the plurality of weight maps may indicate how applicable each kernel is for the various locations in the array of temperature values. There may be a corresponding number of kernels and weight maps. The weighting engine 230 may use a model to compute the plurality of weight maps based on the plurality of kernels. In some examples, the model may include a neural network, such as a de-convolutional neural network, a super-resolution convolutional neural network, or the like. The weighting engine 230 may apply the neural network to the plurality of kernels to determine the plurality of weight maps. For example, there may be a 100×100 array of temperature values and three kernels that each include a 5×5 array of values in an example. The input to the neural network may be the plurality of kernels represented by a 5×5×3 array of values. A second layer may produce an 11×11×3 array of values, a third layer may produce a 33×33×3 array of values, and the output of the neural network may be a 100×100×3 array of weight values. In some examples, the plurality of weight maps may include an array of weight values that is the same size as the plurality of intermediate arrays of values.

The system 200 may include a compositing engine 240. The compositing engine 240 may apply the plurality of weight maps to the plurality of intermediate descriptions to produce weighted intermediate descriptions. For example, the compositing engine 240 may multiply each value in the array of weight values by a corresponding value in the plurality of intermediate arrays of values (e.g., an element-by-element multiplication) to produce a plurality of weighted intermediate arrays of values. The compositing engine 240 may combine the weighted intermediate descriptions to produce an updated description of the physical state. For example, the compositing engine 240 may sum the weighted intermediate arrays of values to produce an array of updated temperature values (e.g., an element-by-element summation of the plurality of weighted intermediate arrays of values with each weighted intermediate array of values as a summand). The updated description of the physical state may include an estimate of the physical state at an earlier or later point in time (e.g., an array of estimated temperature values for an earlier or later point in time). In an example where the calculation engine 220 applies the plurality of kernels to a difference between the first and second arrays of temperature values, summing the intermediate arrays may produce an updated difference array reflecting the differences between temperature vales of the second layer of powder at the earlier or later point in time and the unmodified first array. The compositing engine 240 may add the updated difference array to the unmodified first array to generate the array of estimated temperature values for the earlier or later point in time. In an example with a 100×100×3 array of intermediate values and a 100×100×3 array of weight values, the two 100×100×3 arrays may be multiplied element-by-element, and the three 100×100 arrays of the resulting 100×100×3 array may be summed element-by-element to produce a single 100×100 array of updated values.

The compositing engine 240 may use the weighted maps to determine how much influence each kernel should have on a particular element of the final output. The convolution results from a kernel that produces a larger value in the weight map for a particular location than other kernels will have more impact on the final output than the convolution results from the other kernels and vice versa. Accordingly, the weighting engine 230 and the compositing engine 240 may ensure that the kernels may model the effects of the physical attributes where those physical attributes are relevant and not where those physical attributes are not relevant.

The system 200 may include a training engine 250. The training engine 250 may compare the updated description of the physical state to a true description of the physical state. For example, the thermal imaging device 202 may capture a thermal image at the earlier or later point in time corresponding to the updated description of the physical state. The thermal image at the earlier or later point in time may be converted to the true description of the physical state. For example, the preprocessing engine 204 may correct the thermal image and convert the thermal image into an array of true temperature values. The training engine 250 may compare the array of estimated temperature values to the array of true temperature values. For example, the training engine 250 may compute a loss function, which may include computing the difference, the ratio, the mean squared error, the absolute error, or the like between the array of estimated temperature values and the array of true temperature values. In an example, the array of estimated temperature values and the array of true temperature values may correspond to the difference between temperature values of a second layer of powder at the earlier or later point in time and the temperature values of the first layer of powder immediately prior to addition of the second layer of powder.

The training engine 250 may update the model used by the kernel generation engine 210 and the model used by the weighting engine 230 based on the comparison. For example, when the models are neural networks, the training engine 250 may update the neural networks by backpropagating an error through the neural networks (e.g., the error for each value determined by the training engine 250 when comparing the array of estimated temperature values to the array of true temperature values). The training engine 250 may update weights of the neurons in the neural networks by performing a gradient descent on the loss function. The training engine 250 may use a loss function based on comparing the array of estimated temperature values to the array of true temperature values to update weights for both the neural network used by the kernel generation engine 210 and the neural network used by the weighting engine 230. In some examples, the training data used by the training engine 250 may include input and output arrays of temperature values separated by the same predetermined time period so that the system 200 is trained to estimate thermal diffusion over that time period. The predetermined time period may be determined based on physical science insights, experimental experiences, or the like.

In some examples, the training engine 250 may determine how many kernels should be included in the plurality of kernels or may determine the size of the kernels. The system 200 may be trained using a predetermined number or size of kernels. The training engine 250 may analyze the kernels produced during or after training (e.g., the kernels produced after much of the training has occurred). In examples where the kernel is an array of values, the training engine 250 may determine whether a kernel contains substantially all zero values or entirely all zero values. The kernel may contain substantially all zero values if all but a small percentage or number of values or zero, if all the values are near zero relative to other kernels, both, or the like. The training engine 250 may reduce the number of kernels included in the plurality of kernels based on how many kernels contain substantially all zero values. If none of the plurality of kernels include substantially all zero values and the number of kernels has not been decreased previously, the training engine 250 may increase the number of kernels. Similarly, the training engine 250 may analyze the kernels to determine whether values near the edges of the array are substantially all zero. The training engine 250 may decrease or increase the size of the kernels based on whether the values near the edges of the array or substantially all zero. The training engine 250 may restart training using the new number of kernels or the new size kernels.

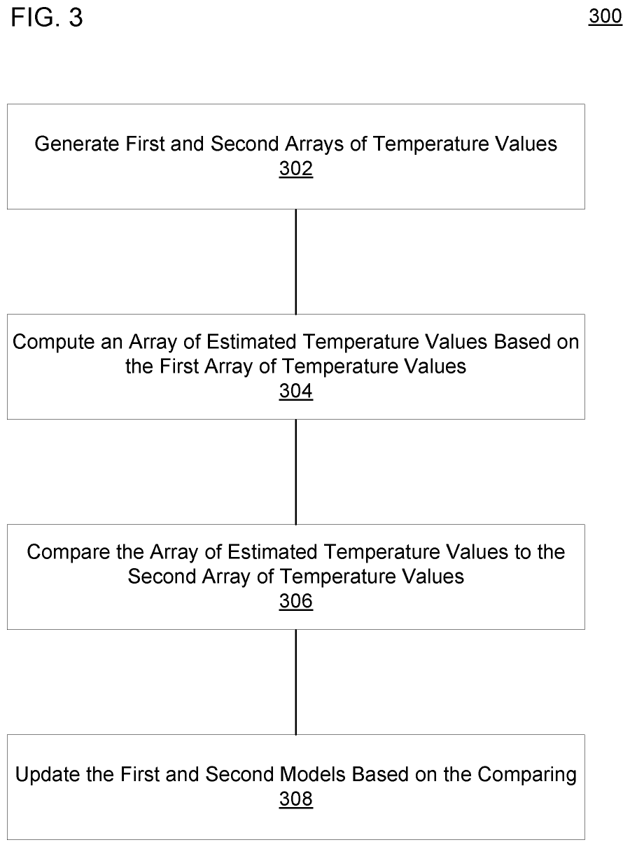

FIG. 3 is a flow diagram of an example method 300 to update models to generate a kernel. A processor may perform the method 300. At block 302, the method 300 may include generating first and second arrays of temperature values. For example, generating the first and second arrays of temperature values may include receiving temperature values from a sensor or remote device, deriving the temperature values from stored data, or the like.

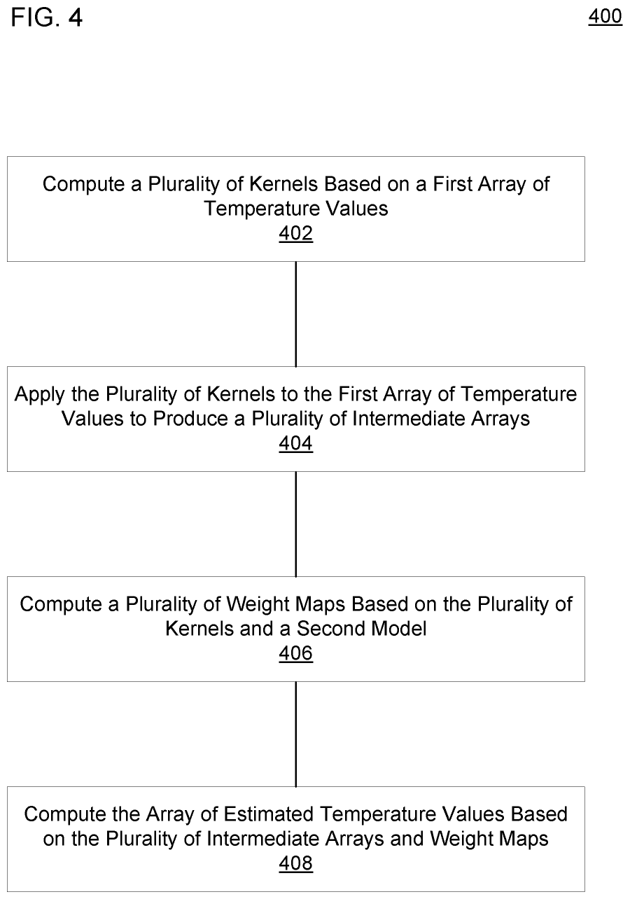

Block 304 may include computing an array of estimated temperature values based on the first array of temperature values. The first array of temperature values may be associated with a first time, and the second array of temperature values may be associated with a second time. Computing the array of estimated temperature values may include computing estimated temperature values associated with the second time using the first array of temperature values associated with the first time. As discussed below with reference to FIG. 4, computing the array of estimated temperature values may include using first and second models to compute the array of estimated temperature values.

At block 306, the method 300 may include comparing the array of estimated temperature values to the second array of temperature values. For example, the array of estimated temperature values may be an estimate of the second array of temperature values. Accordingly, comparing the array of estimated temperature values to the second array of temperature values may determine the accuracy of the estimates. Block 308 may include updating the first and second models based on the comparing. For example, the first and second models may be updated to improve the accuracy of the array of estimated temperature values generated at block 304. Referring to FIG. 2, in an example, the thermal imaging device 202 or the preprocessing engine 204 may perform block 302; the kernel generation engine 210, the calculation engine 220, the weighting engine 230, or the compositing engine 240 may perform block 304; and the training engine 250 may perform blocks 306 or 308.

FIG. 4 is a flow diagram of an example method 400 to compute an array of estimated temperature values. A processor may perform the method 400. At block 402, the method 400 may include computing a plurality of kernels based on a first array of temperature values and a first model. Each kernel may relate to a physical attribute of a physical system. The first model may relate arrays of temperature values to kernels representative of the effects associated with that physical attribute.

Block 404 may include applying the plurality of kernels to the first array of temperature values to produce intermediate arrays. For example, the plurality of kernels may indicate how various physical attributes will affect the first array of temperature values. Applying the kernels may include computing the effects of those physical attributes on the first array of temperature values. In an example, applying the plurality of kernels may include convolving each kernel with the first array of temperature values to produce a corresponding intermediate array. At block 406, the method 400 may include computing a plurality of weight maps based on the plurality of kernels and a second model. The second model may relate the kernels to their relevance at particular locations. For example, some physical attributes may have dominant effects in a first area while other physical attributes may have dominant effects in a second area. Accordingly, the plurality of weight maps may indicate how much the physical attributes associated with each kernel affects the temperature value at each location.

Block 408 may include computing the array of estimated temperature values based on the plurality of intermediate arrays and the plurality of weight maps. For example, each intermediate array may have a corresponding weight map (e.g., both may be generated from one of the plurality of kernels). The weight map may be applied to its corresponding intermediate array, and the intermediate arrays may be combined to produce the array of estimated temperature values. Applying the weight map may weight the value at each location of the intermediate array to reflect the relevance of the kernel producing that value to that location. Combining the intermediate arrays may combine the effects of the various physical attributes to produce an estimate of the temperature value that results from those effects. Referring to FIG. 1, in an example, the kernel generation engine 110 may perform block 402; the calculation engine 120 may perform block 404; the weighting engine 130 may perform block 406; and the compositing engine 140 may perform block 408.

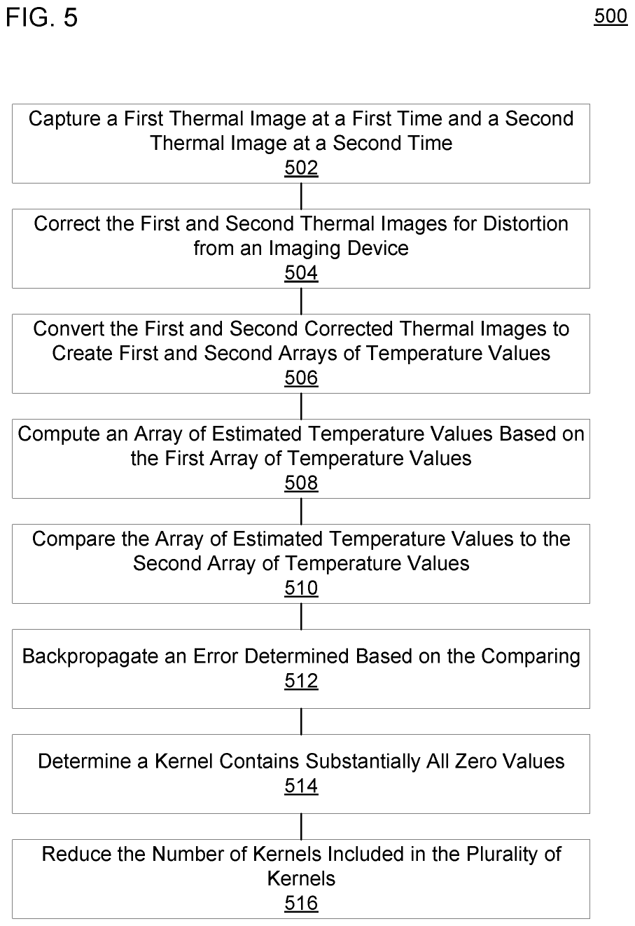

FIG. 5 is a flow diagram of another example method 500 to update models to generate a kernel. A processor may perform the method 500. At block 502, the method 500 may include capturing a first thermal image at a first time and a second thermal image at a second time. Capturing the first and second thermal images may include sensing infrared radiation, such as with a thermal imaging device. In an example, the thermal images may be of a top layer of a print target, and the thermal images may be captured during printing.

Block 504 may include correcting the first and second thermal images for distortion from an imaging device to create first and second corrected thermal images. For example, a lens of the thermal imaging device may cause curvature such that straight lines being imaged appear as curved lines in the image. Accordingly, correcting the first and second thermal images may include undoing the distortion caused by the imaging device so that straight lines being imaged appear as straight lines in the corrected thermal images.

At block 506, the method 500 may include converting the first and second corrected thermal images to create the first and second arrays of temperature values. The corrected thermal images may include an array of measured intensities of infrared radiation. The measured intensities of infrared radiation may correspond to temperatures or emissivities of the image target. Accordingly, each intensity in the array of measured intensities may be used to calculate a corresponding temperature value.

Block 508 may include computing an array of estimated temperature values based on the first array of temperature values. The array of estimated temperature values may be computed using first and second models. For example, the array of estimated temperature values may be computed in the manner discussed above with reference to FIG. 4. The first and second models may include neural networks. For example, each model may include a neural network, such as a convolutional neural network, a de-convolutional neural network, a super-resolution convolutional neural network, or the like.

At block 510, the method 500 may include comparing the array of estimated temperature values to the second array of temperature values. For example, the array of estimated temperature values may be an estimate of the temperature values at the second time while the second array of temperature values is the true temperature values at that second time. Accordingly, comparing the array of estimated temperature values to the second array of temperature values may include computing an error for each element of the arrays using a loss function.

Block 512 may include backpropagating an error determined based on the comparing. For example, the error may be determined based on a loss function. The weights used by the neural networks of the first and second models may be updated based on a gradient of the loss function. Backpropagating the error may include finding weights that minimize the error, for example, by performing a gradient descent of the loss function. In some examples, a training data set may include a set of first and second arrays of temperature values or a set of first and second thermal images that may be used to update the weights or the neural networks.

At block 514, the method 500 may include determining a kernel contains substantially all zero values (e.g., a kernel used to compute the array of estimated temperature values as discussed with reference to FIG. 4). After some amount of training, a kernel may begin to approach having substantially or entirely all zero values. At block 516, the method 500 may include reducing the number of kernels included in the plurality of kernels. For example, a kernel converging towards all zero values may indicate that the plurality of kernels includes more kernels than are needed to model the physical attributes. Accordingly, the unnecessary kernels may be discarded. In some examples, training can be restarted with the updated number of kernels. In an example, the thermal imaging device 202 of FIG. 2 may perform block 502; the preprocessing engine 204 may perform blocks 504 or 506; the kernel generation engine 210, the calculation engine 220, the weighting engine 230, or the corn positing engine 240 may perform block 508; and the training engine 250 may perform blocks 510, 512, 514, or 516.

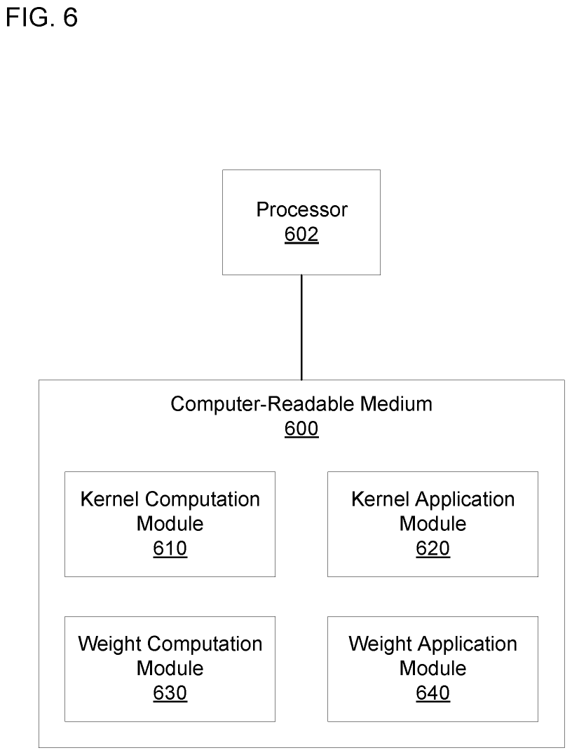

FIG. 6 is a block diagram of an example computer-readable medium 600 including instructions that, when executed by a processor 602, cause the processor 602 to generate a kernel based on a physical state. In an example, the physical state may be represented by an array of temperature values. The computer-readable medium 600 may be a non-transitory computer-readable medium, such as a volatile computer-readable medium (e.g., volatile RAM, a processor cache, a processor register, etc.), a non-volatile computer-readable medium (e.g., a magnetic storage device, an optical storage device, a paper storage device, flash memory, read-only memory, non-volatile RAM, etc.), and/or the like. The processor 602 may be a general purpose processor or special purpose logic, such as a microprocessor (e.g., a central processing unit, a graphics processing unit, etc.), a digital signal processor, a microcontroller, an ASIC, an FPGA, a programmable array logic (PAL), a programmable logic array (PLA), a programmable logic device (PLD), etc. The computer-readable medium 600 or the processor 602 may be distributed among a plurality of computer-readable media or a plurality of processors.

The computer-readable medium 600 may include a kernel computation module 610. As used herein, a “module” (in some examples referred to as a “software module”) is a set of instructions that when executed or interpreted by a processor or stored at a processor-readable medium realizes a component or performs a method. The kernel computation module 610 may include instructions that, when executed, cause the processor 602 to compute a kernel based on an array of temperature values using a first neural network. For example, the kernel computation module 610 may cause the processor 602 to use the array of temperature values as an input to the first neural network. The kernel computation module 610 may cause the processor 602 to use the first neural network to compute the kernel as an output from the first neural network.

The computer-readable medium 600 may include a kernel application module 620. The kernel application module 620 may cause the processor 602 to apply the kernel to the array of temperature values to produce an intermediate array of values. For example, the kernel application module 620 may cause the processor 602 to compute the intermediate array based on the kernel and the array of temperature values. Thus, the array of temperature values may be used by the kernel computation module 610 to compute the kernel that is applied to the same array of temperature values by the kernel application module 620.

The computer-readable medium 600 may include a weight computation module 630. The weight computation module 630 may cause the processor 602 to compute a weight map based on the kernel using a second neural network. For example, the weight computation module 630 may cause the processor 602 to use the kernel as an input to the second neural network. The weight computation module 630 may cause the processor 602 to use the second neural network to compute the weight map as an output from the first neural network. The weight map may be the same size as the intermediate array and include a weight value corresponding to each value in the intermediate array.

The computer-readable medium 600 may include a weight application module 640. The weight application module 640 may cause the processor 602 to apply the weight map to the intermediate array to produce an updated array of temperature values. For example, the weight application module 640 may cause the processor 602 to adjust the values of the intermediate array based on the weight map. In an example, when executed by the processor 602, the kernel computation module 610 may realize the kernel generation engine 110 of FIG. 1; the kernel application module 620 may realize the calculation engine 120; the weight computation module 630 may realize the weighting engine 130; and the weight application module 640 may realize the compositing engine 140.

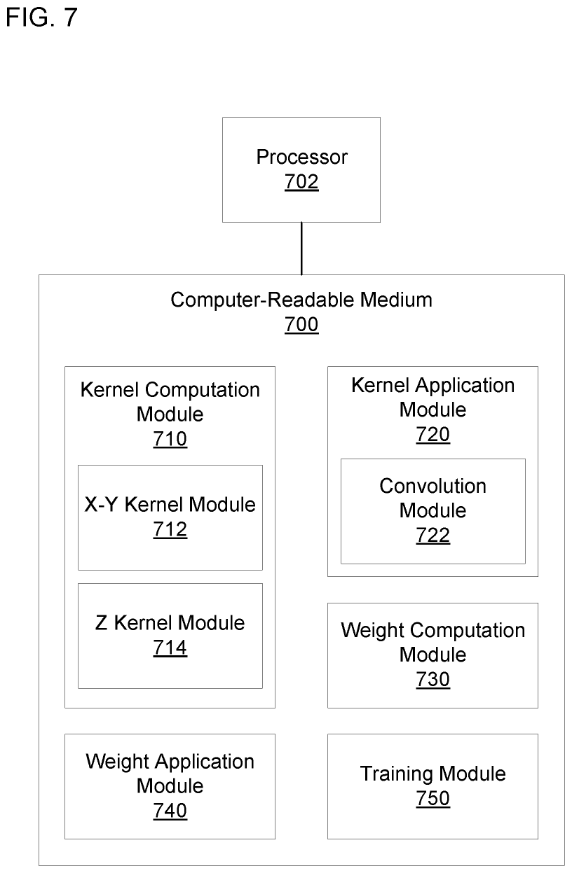

FIG. 7 is a block diagram of another example computer-readable medium 700 including instructions that, when executed by a processor 702, cause the processor 702 to generate a kernel based on a physical state. In an example, the physical state again may be represented by an array of temperature values. The computer-readable medium 700 may include a kernel computation module 710. The kernel computation module 710 may include instructions that, when executed, cause the processor 702 to compute a kernel based on the array of temperature values using a first neural network. For example, the kernel computation module 710 may cause the processor 702 to simulate the first neural network and use the array of temperature values as an input to the first neural network. The kernel computation module 710 may cause the processor 702 to produce a plurality of kernels based on the array of temperature values when simulating the first neural network. In some examples, the first neural network may include a convolutional neural network.

The kernel computation module 710 may include an x-y kernel module 712 and a z kernel module 714. The x-y kernel module 712 may cause the processor 702 to receive an array of temperature values corresponding to a single layer of powder in a three-dimensional printer and to compute a kernel based on that array of temperature values. In some examples, the array of temperature values may include an array of differences between temperature values of a first layer of powder in a three-dimensional printer and temperature values of a second layer of powder in the three-dimensional printer. For example, the thermal diffusion in the three-dimensional printer in the x or y directions may be different than the thermal diffusion in the three-dimensional printer in the z direction. The z kernel module 714 may cause the processor 702 to receive an array of temperature values corresponding to differences between temperature values of the first layer and temperature values of the second layer. For example, the array of temperature values may be a difference array computed by an element-by-element subtraction between an array associated with temperature values of the first layer and an array associated with temperature values of the second layer). The z kernel module 714 may cause the processor 702 to compute a kernel based on the array of temperature values corresponding to differences. In some examples, the x-y kernel module 712 and the z kernel module 714 may each be associated with different neural network than the other, and each may cause the processor 702 to compute kernels using its associated neural network. In an example, the z kernel module 714 may cause the processor to compute a plurality of kernels based on an array of temperature values for a single layer of powder, but the plurality of kernels may be applicable to an array of temperature values corresponding to differences in temperature values. In examples where the z kernel module 714 causes the processor 702 to compute the plurality of kernels, the kernels may be applied (as discussed below) to the difference array, and the updated array of temperature values (discussed below) may be an updated array of differences (e.g., regardless of the input to the z kernel module 714).

The computer-readable medium 700 may include a kernel application module 720. The kernel application module 720 may cause the processor 702 to apply the kernel to the array of temperature values to produce an intermediate array. In an example, the kernel application module 720 may include a convolution module 722. The convolution module 722 may cause the processor 702 to convolve the kernel with the array of temperature values to produce the intermediate array. In an example, the kernel may model thermal diffusion between an element of the array of temperature values and nearby elements of the array of temperature values. The kernel may be represented as an array of values that when convolved with the array of temperature values models the thermal energy transferred among the elements of the array. In examples that include a plurality of kernels, the convolution module 722 may cause the processor 702 to convolve each kernel with a copy of the array of temperature values.

The computer-readable medium 700 may include a weight computation module 730. The weight computation module 730 may cause the processor 702 to compute a weight map based on the kernel using a second neural network. For example, the weight computation module 730 may cause the processor 702 to simulate the second neural network and use the kernel as an input to the second neural network. In some examples, the second neural network may include a de-convolutional neural network, a super-resolution convolutional neural network, or the like. In examples that include a plurality of kernels, the weight computation module 730 may cause the processor 702 to compute a plurality of weight maps based on the plurality of kernels when simulating the second neural network.

The computer-readable medium 700 may include a weight application module 740. The weight application module 740 may cause the processor 702 to apply the weight map to the intermediate array to produce an updated array of temperature values. For example, the weight application module 740 may cause the processor 702 to multiply the weight map by the intermediate array element-by-element. The kernel may model particular physical attributes of the thermal diffusion among elements of the array of temperature values, and the weight map may reflect the relevance of those particular physical attributes to different areas of the array of temperature values. For example, the weight map may include a smaller value that reduces the value of an element of the intermediate array where the particular physical attributes are less relevant, and the weight map may include a larger value that increases or does not reduce as much the value of an element of the intermediate array where the particular physical attributes are more relevant. In examples that include a plurality of kernels, the weight application module 740 may cause the processor 702 to multiply each weight map by a corresponding intermediate array element-by-element. The weight application module 740 may cause the processor 702 to sum together the results from the multiplications element-by-element to compute the updated array of temperature values.

In some examples, the updated array of temperature values may be computed based on an array of temperature values and an array of non-temperature values. For example, the kernel computation module 710 may cause the processor 702 to compute an additional kernel based on the array of non-temperature values. The kernel application module 720 may cause the processor 702 to apply the additional kernel to the array of temperature values or the array of non-temperature values to produce an additional intermediate array. The weight computation module 730 may cause the processor 702 to compute an additional weight map based on the additional kernel. The weight application module 740 may cause the processor 702 to composite the intermediate array with the additional intermediate array based on the weight map and the additional weight map. For example, the weight application module 740 may cause the processor 702 to multiply the additional intermediate array by the additional weight map element-by-element. The weight application module 740 may cause the processor 702 to sum together the results from the multiplications element-by-element to compute the updated array of temperature values. In examples including a plurality of kernels based on the array of temperature values, the weight application module 740 may cause the processor 702 to sum together results flowing from the plurality of kernels with results flowing from the additional kernel.

The computer-readable medium 700 may include a training module 750. The training module 750 may cause the processor 702 to calculate an error between the updated array of temperature values and an array of true temperature values. The training module 750 may cause the processor 702 to adjust the first and second neural networks based on the error. For example, the training module 750 may cause the processor 702 to compute the error between the updated array of temperature values and the array of true temperature values using a loss function, and the training module 750 may cause the processor 702 to use a gradient of the loss function to minimize the error. The training module 750 may cause the processor 702 to update weights in the first and second neural networks based on the loss function applied to the updated array of temperature values and the array of true temperature values. Referring to FIG. 2, in an example, when executed by the processor 702, the kernel computation module 710 may realize the kernel generation engine 210; the kernel application module 720 may realize the calculation engine 220; the weight computation module 730 may realize the weighting engine 230; the weight application module 740 may realize the compositing engine 240; and the training module 750 may realize the training engine 250.

The above description is illustrative of various principles and implementations of the present disclosure. Numerous variations and modifications to the examples described herein are envisioned. Accordingly, the scope of the present application should be determined only by the following claims.

What is claimed is:

1. A system comprising:
a kernel generation engine to generate a plurality of kernels based on a description of a physical state, wherein the plurality of kernels are generated based on applying a neural network to the description of the physical state;
a calculation engine to apply the plurality of kernels to the description of the physical state to produce a plurality of intermediate descriptions;
a weighting engine to determine a plurality of weight maps based on the plurality of kernels; and
a compositing engine to apply the plurality of weight maps to the plurality of intermediate descriptions to produce weighted intermediate descriptions and to combine the weighted intermediate descriptions to produce an updated description of the physical state.

2. The system of claim 1, wherein the description of the physical state comprises an array of temperature values at a point in time.

3. The system of claim 2, wherein the updated description of the physical state comprises an array of estimated temperature values for an earlier or later point in time.

4. The system of claim 1, wherein the weighting engine is to apply a neural network to the plurality of kernels to determine the plurality of weight maps.

5. The system of claim 4, wherein the kernel generation engine comprises a convolutional neural network and the weighting engine comprises a super-resolution convolutional neural network.

6. A method comprising:
generating first and second arrays of temperature values;
computing an array of estimated temperature values based on the first array of temperature values, wherein computing the array of estimated temperature values comprises:
computing a plurality of kernels based on the first array of temperature values and a first model,
applying the plurality of kernels to the first array of temperature values to produce a plurality of intermediate arrays,
computing a plurality of weight maps based on the plurality of kernels and a second model, and
computing the array of estimated temperature values based on the plurality of intermediate arrays and the plurality of weight maps;
comparing the array of estimated temperature values to the second array of temperature values; and
updating the first and second models based on the comparing.

7. The method of claim 6, wherein generating the first and second arrays comprises:
capturing a first thermal image at a first time and a second thermal image at a second time;
correcting the first and second thermal images for distortion from an imaging device to create first and second corrected thermal images; and
converting the first and second corrected thermal images to create the first and second arrays of temperature values.

8. The method of claim 6, wherein the first and second models comprise neural networks, and wherein updating the first and second models comprises backpropagating an error determined based on the comparing.

9. The method of claim 6, wherein applying the plurality of kernels comprises convolving each kernel with the first array of temperature values to produce a corresponding intermediate array.

10. The method of claim 6, further comprising determining a kernel contains substantially all zero values, and reducing the number of kernels included in the plurality of kernels.

11. A non-transitory computer-readable medium comprising instructions that, when executed by a processor, cause the processor to:
compute a kernel based on an array of temperature values using a first neural network;
apply the kernel to the array of temperature values to produce an intermediate array;
compute a weight map based on the kernel using a second neural network; and
apply the weight map to the intermediate array to produce an updated array of temperature values.

12. The computer-readable medium of claim 11, wherein the kernel models thermal diffusion between an element of the array of temperature values and nearby elements of the array of temperature values, and wherein the instructions cause the processor to convolve the kernel with the array of temperature values to produce the intermediate array.

13. The computer-readable medium of claim 11, wherein the instructions cause the processor to calculate an error between the updated array of temperature values and an array of true temperature values and adjust the first and second neural networks based on the error.

14. The computer-readable medium of claim 11, wherein the array of temperature values comprises an array of differences between temperature values of a first layer of powder in a three-dimensional printer and temperature values of a second layer of powder in the three-dimensional printer.

15. The computer-readable medium of claim 11, further comprising computing an additional kernel based on an array of non-temperature values, applying the additional kernel to the array of temperature values to produce an additional intermediate array, computing an additional weight map based on the additional kernel, and compositing the intermediate array with the additional intermediate array based on the weight map and the additional weight map.
